(19) United States
(12) Patent Application Publication
(10) Pub. No.: US 2024/0273257 A1
(43) Pub. Date: Aug. 15, 2024

(54) SYSTEM AND METHOD FOR SIMULATING OUTCOMES RELATING TO EMERGENCY MANAGEMENT SITUATIONS

(71) Applicant: KPMG LLP, New York, NY (US)

(72) Inventors: Christopher Gottlieb, Mooresville, NC (US); James Conley Booth, Rockport, TX (US); Bharat C. Gorantla, Austin, TX (US); Marcos Salganicoff, Douglassville, PA (US)

(21) Appl. No.: 18/440,409

(22) Filed: Feb. 13, 2024

Related U.S. Application Data
(60) Provisional application No. 63/445,073, filed on Feb. 13, 2023.

(51) Int. Cl. G06F 30/20; G06Q 10/0631; G06Q 10/0833; G06Q 10/087

(52) U.S. Cl. CPC G06F 30/20; G06Q 10/06315; G06Q 10/0833; G06Q 10/087

(57) ABSTRACT

The invention relates to computer-implemented systems and methods for generating a computerized replica of an entire supply chain, capable of simulating how effectively and efficiently products are likely to be distributed under future disruptive conditions. For Emergency Management, an embodiment of the present invention may replicate various supply conditions facing essential products and simulate how a department is likely to perform when faced with a specific emergency event. An embodiment of the present invention may forecast how fast inventory will run out, the availability of alternative supplies, optimal points of distribution, and where the major points of vulnerability are throughout an entire network.

### CROSS REFERENCE TO RELATED APPLICATIONS

The application claims priority to U.S. Provisional Application 63/445,073 (Attorney Docket No. 055089.0000107), filed Feb. 13, 2023, the contents of which are incorporated by reference herein in their entirety.

### FIELD OF THE INVENTION

The present invention relates to systems and methods for simulating potential outcomes in various enterprise level events incorporating the procurement and use of materials from multiple sources.

### BACKGROUND

The complexity and uncertainty within the supply chain for essential products has never been higher than what Emergency Management departments are facing today. In today's environment, there is extreme uncertainty about the availability of supply across different product sources, highly volatile costs, and inconsistent lead times for product distribution due to fast-changing supply chain conditions.

These supply challenges are disrupting the ability of Emergency Management (EM) teams to adequately prepare for and respond to future disasters. It is more difficult today for EM teams to know how much product to buy, where to store these products, what alternative sources will be available, how long supplies will last, and how to best distribute limited inventory (during an emergency) to residents based on needs. Many teams also find themselves facing the risk of “over-buying” which can lead to significant write offs and disposals based on product expirations.

It would be desirable, therefore, to have a system and method that could overcome the foregoing disadvantages.

### SUMMARY

According to one embodiment, the invention relates to a computer-implemented system that implements a simulation tool that analyzes and projects procurement data for various emergency events. The system comprises: an input that communicates with one or more data sources; a memory component that stores and manages data from the one or more data sources; and a computer processor coupled to the interface and the memory component and further programmed to perform the steps of: identifying one or more inquiries relating to a supply chain projection in an emergency event; importing, via the input, one or more data files relating to an enterprise supply chain relevant to the emergency event wherein the one or more data files comprise: supplier data, product data, external data and government data; identifying, via the computer processor, a set of simulation parameters wherein the set of simulation parameters relate to an emergency type and one or more products to simulate; responsive to the set of simulation parameters, activating a set of core model components relating to a supply chain simulation; executing the supply chain simulation to generate at least one supply chain result, wherein the supply chain result comprises a total delivered cost and a number of consumers above a required daily supply; and providing, via an interface, a graphical representation of the at least one supply chain result.

According to another embodiment, the invention relates to a computer-implemented method that implements a simulation tool that analyzes and projects procurement data for various emergency events. The method comprises the steps of: identifying, via an input, one or more inquiries relating to a supply chain projection in an emergency event; importing, via the input, one or more data files relating to an enterprise supply chain relevant to the emergency event wherein the one or more data files comprise: supplier data, product data, external data and government data; identifying, via a computer processor, a set of simulation parameters wherein the set of simulation parameters relate to an emergency type and one or more products to simulate; responsive to the set of simulation parameters, activating a set of core model components relating to a supply chain simulation; executing the supply chain simulation to generate at least one supply chain result, wherein the supply chain result comprises a total delivered cost and a number of consumers above a required daily supply; and providing, via a user interface, a graphical representation of the at least one supply chain result.

An embodiment of the present invention is directed to supply chain innovations for Emergency Management to develop effective plans, training and data analytics that lead to more resilient communities and states. The supply chain innovations leverage big data, advanced analytics, and artificial intelligence (AI)/machine learning (ML) to significantly improve supply chain resiliency, emergency preparedness and response operations.

These and other advantages will be described more fully in the following detailed description.

### BRIEF DESCRIPTION OF THE DRAWINGS

In order to facilitate a fuller understanding of the present invention, reference is now made to the attached drawings. The drawings should not be construed as limiting the present invention, but are intended only to illustrate different aspects and embodiments of the invention.

FIG. 1 is an exemplary system diagram, according to an embodiment of the present invention.

FIG. 2 is an exemplary flow diagram, according to an embodiment of the present invention.

FIG. 3 is an exemplary illustration of data files, according to an embodiment of the present invention.

FIG. 4 is an exemplary user interface, according to an embodiment of the present invention.

FIG. 5 illustrates an example of simulation parameters, according to an embodiment of the present invention.

FIG. 6 illustrates an example of simulation parameters, according to an embodiment of the present invention.

FIG. 7 is an exemplary user interface that illustrates attribute data inputs, according to an embodiment of the present invention.

FIG. 8 is an exemplary user interface, according to an embodiment of the present invention.

FIG. 9 is an exemplary user interface of distribution segments, according to an embodiment of the present invention.

FIG. 10 is an exemplary user interface that illustrates center of gravity and estimated supply level, according to an embodiment of the present invention.

FIG. 11 is an exemplary user interface, according to an embodiment of the present invention.

FIG. 12 is an exemplary user interface that illustrates supply channels, according to an embodiment of the present invention.

FIG. 13 is an exemplary user interface, according to an embodiment of the present invention.

FIG. 14 is an exemplary user interface, according to an embodiment of the present invention.

FIG. 15 is an exemplary user interface that illustrates an updated simulation, according to an embodiment of the present invention.

FIG. 16 is an exemplary user interface that illustrates an ability to provide source details, according to an embodiment of the present invention.

FIG. 17 is an exemplary user interface that illustrates an updated simulation, according to an embodiment of the present invention.

FIG. 18 is an exemplary user interface that illustrates updated source details, according to an embodiment of the present invention.

FIG. 19 is an exemplary user interface that illustrates scenario comparison details, according to an embodiment of the present invention.

FIG. 20 is an exemplary user interface that details severity index, according to an embodiment of the present invention.

FIG. 21 is an exemplary user interface that provides projected supply risk, according to an embodiment of the present invention.

FIG. 22 is an exemplary user interface, according to an embodiment of the present invention.

FIG. 23 is an exemplary system diagram, according to an embodiment of the present invention.

### DETAILED DESCRIPTION

Exemplary embodiments of the invention will now be described in order to illustrate various features of the invention. The embodiments described herein are not intended to be limiting as to the scope of the invention, but rather are intended to provide examples of the components, use, and operation of the invention.

An embodiment of the present invention is directed to generating a computerized replica of a supply chain that simulates how effectively and efficiently products or services are likely to be distributed under a disruptive condition (which may be referred to as “Digital Twins”). The computerized replica may include an entire supply chain, a portion of or a select part. For Emergency Management, Digital Twins may replicate various supply conditions facing essential products and simulate how a department is likely to perform when faced with a specific emergency event and/or condition. An embodiment of the present invention may forecast how fast inventory will run out, the availability of alternative supplies, optimal points of distribution, and/or where the major points of vulnerability are throughout an entire network.

An embodiment of the present invention may generate a digital replica of a physical operating system and then simulate how operations may be carried out over a defined period of time. Other conditions, restrictions and/or scenarios may be considered. The digital replica may use real-time market signals to anticipate supply and demand disruptions before they happen. In addition, specific points of vulnerability and/or risk may be defined and further translated to cost, performance as well as other factors. Impact areas may include: emergency management; transportation; building construction, health and/or education.

An embodiment of the present invention may run smart simulations based on information about an environment. By understanding certain attributes, a model may make reliable predictions relating to emergency events, etc. In addition, the system may continually learn and adjust as needed.

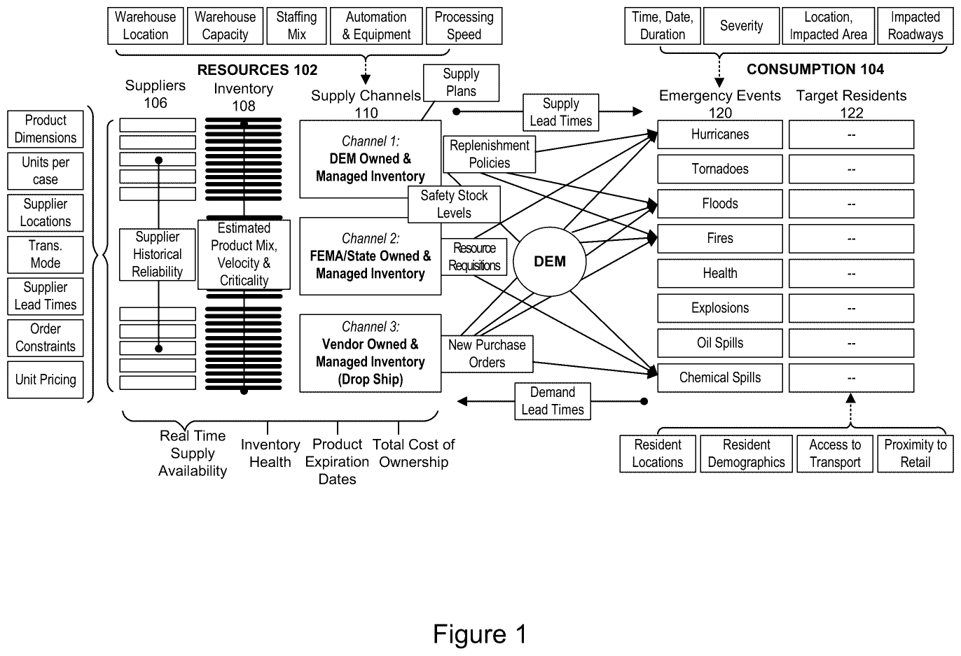

FIG. 1 is an exemplary system diagram, according to an embodiment of the present invention. FIG. 1 illustrates Resources 102 and Consumption 104 within an emergency management system. Resources 102 may include: Suppliers 106, Inventory 108 and Supply Channels 110. Suppliers 106 may include supplier historical reliability. Other factors may include: product dimensions, units per case, supplier locations, transportation mode, supplier lead times, order constraints and unit pricing. Inventory 108 may include estimated product mix, velocity and criticality. Other suppliers and inventory may be identified.

Supply Channels 110 may be defined by: Warehouse Location, Warehouse Capacity, Staffing Mix, Automation & Equipment and Processing Speed. Supply Channels 110 may include: Department of Emergency Management (DEM) Owned and Managed Inventory (Channel 1); FEMA/State Owned and Managed Inventory (Channel 2) as well as Vendor Owned and Managed Inventory (Channel 3). Other channels and sources of supply may be identified.

Resources 102 may be used to provide real-time supply availability, inventory health, product expiration dates and total cost of ownership.

Consumption 104 may relate to: Emergency Events 120 and Target Residents 122. Emergency Events 120 may be defined by: Time, Date, Duration; Severity; Location, Impacted Area and Impacted Roadways. Emergency Events 120 may be weather-related, accident related, threat-related, etc. For example, Emergency Events 120 may include: hurricanes, tornadoes, floods, fires, health, explosions, oil spills, chemical spills, etc. Other events may be identified. Target Residents 122 may include: resident locations, resident demographics, access to transportation, proximity to retail and other characteristics.

FIG. 1 also illustrates the connections between Resources 102 and Consumption 104. The connections may represent supply lead times and demand lead times as well as how each Supply Channel 110 addresses certain emergency events 120. Supplier Channels 110 may consider supply plans, replenishment policies, safety stock levels. Other considerations may include: resource requisitions, new purchase orders, etc.

An embodiment of the present invention may address various use cases. Sample uses cases may consider: how long before essential products run out; alternate sources of supply to be pre-secured; optimal points of distribution to best reach “at-risk” residents; allocating newly acquired supply to distribution points; which products in stock require new replenishment and inventory management policies; impact of losing access to major port, bridge, roadway, etc.; what specialized labor sources are at risk of being in short supply (for a defined event); and optimal network of shelters (e.g., locations, capacity, supplies, etc.) for a defined event, etc.

Key characteristics may include: constructed to solve well-defined use cases; built from bottom-up (e.g., large volumes of disaggregated data); data sources internal and external; covers inter-dependencies across operations; performs “what-if” scenario modeling to drive proactive decisions; and uses AI/ML to recommend different courses of action; and estimates impact on performance, cost, etc.

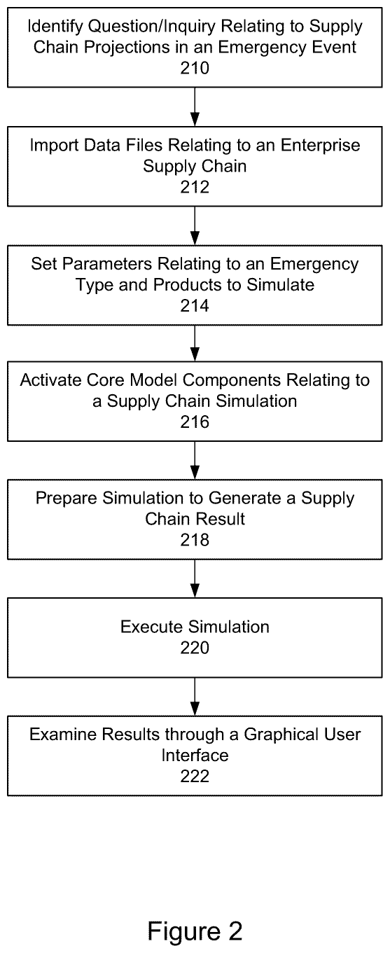

FIG. 2 is an exemplary flow diagram, according to an embodiment of the present invention. At step 210, a question or inquiry relating to supply chain projections in an emergency event may be identified. At step 212, data files relating to an enterprise supply chain may be imported or otherwise accessed. At step 214, one or more parameters relating to an emergency type and products to simulate may be set. At step 216, core model components relating to a supply chain simulation may be activated. At step 218, a simulation to generate at least one supply chain result may be prepared. At step 220, the simulation may be executed. At step 222, results of the simulation may be examined through a graphical representation of the supply chain result. While the process of FIG. 2 illustrates certain steps performed in a particular order, it should be understood that the embodiments of the present invention may be practiced by adding one or more steps to the processes, omitting steps within the processes and/or altering the order in which one or more steps are performed. Additional details for each step are provided below.

At step 210, a question or inquiry relating to supply chain projections in an emergency event may be identified. Example questions may include: how long would a supply of essential products last if an earthquake occurred at a specific location (e.g. on the New Madrid fault line); what would be the estimated impact (on supply conditions) of different proactive mitigation actions; and what would be the total cost outlook of different emergency response scenarios; etc. Other queries may be automatically generated based on a set of conditions and/or other trigger.

At step 212, data files relating to an enterprise supply chain may be imported or otherwise accessed. Data files may include: supplier data; product data; other external data; and government data.

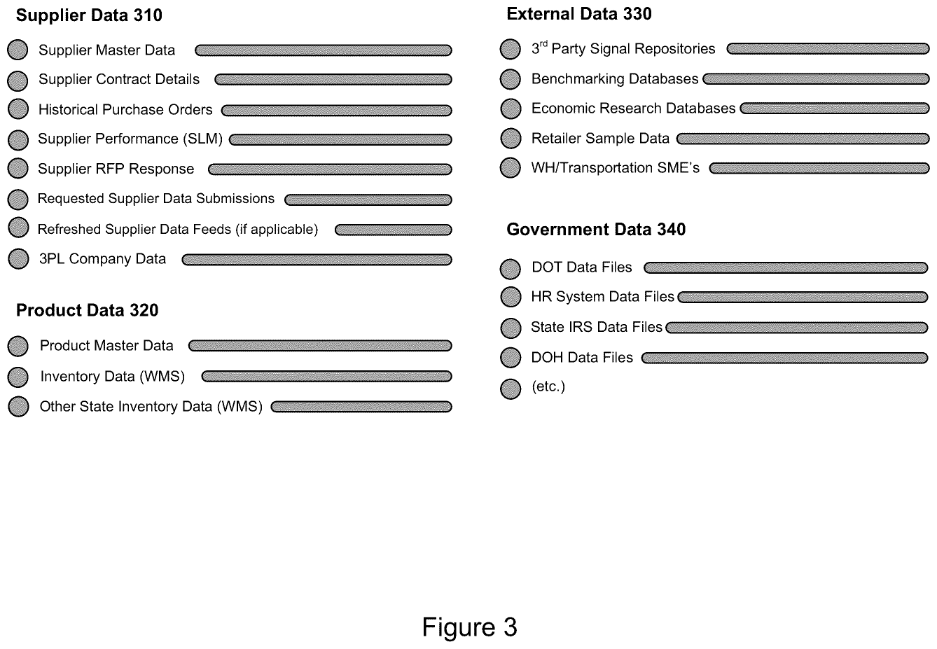

FIG. 3 is an exemplary illustration of data files, according to an embodiment of the present invention. Data may include Supplier Data 310, Product Data 320, External Data 330, Government Data 340, etc. Data may be accessed/received through various sources, internal as well as external. Various types of data sources may be supported, e.g., data feeds, databases, storage devices, government entities, social media, public resources, aggregated data, etc.

As shown in FIG. 3, Supplier Data 310 may include supplier master data, supplier contract details, historical purchase orders, supplier performance, supplier RFP responses, requested supplier data submission, refreshed supplier data feeds, company data, etc.

Product Data 320 may include product master data, inventory data, state inventory data, etc.

External Data 330 may include third party signal repositories, benchmarking databases, economic research databases, retailer sample data, transportation subject matter experts, etc.

Government Data 340 may include department of transportation (DOT) data files, human resources (HR) system data files, state IRS data files, department of health (DOH) data files, etc. Other types of data may be accessed and may vary based on the type of emergency management situation or scenario.

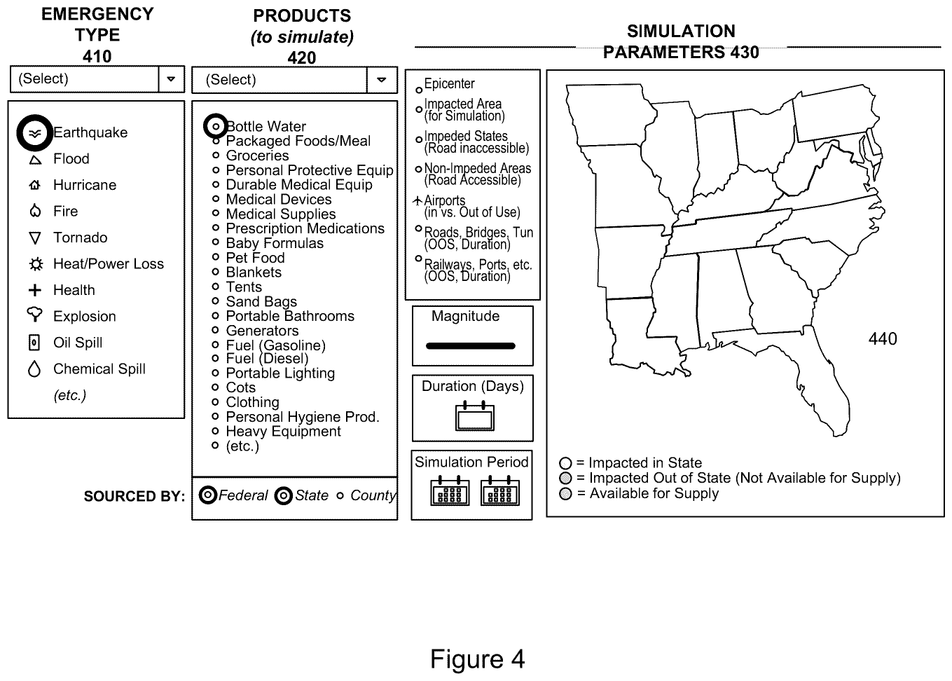

At step 214, one or more parameters relating to an emergency type and products to simulate may be set. FIGS. 4-6 are exemplary user interfaces, according to an embodiment of the present invention. As shown in FIGS. 4-6, parameters may include emergency type and products.

FIG. 4 illustrates Emergency Type 410, Products (to simulate) 420 and Simulation Parameters 430. Emergency Type 410 may include Earthquake, Flood, Hurricane, Fire, Tornado, Heat/Power Loss, Health, Explosion, Oil Spill, Chemical Spill, etc. Products (to simulate) 420 may include various supplies, essentials, etc. For example, products to simulate may include bottle water, packaged food/meals, groceries, personal protective equipment, durable medical equipment, medical devices, medical supplies, prescription medications, baby formula, pet food, blankets, tents, sand bags, portable bathrooms, generators, fuel (gasoline, diesel), portable lighting, cots, clothing, personal hygiene products, heavy equipment, etc. Products may be sourced by various entities, including federal, state, county, private, donors, etc.

In the example of FIG. 4, an emergency type has been identified as “Earthquake,” products to simulate has been selected for “Bottled Water” and sources are identified as “Federal” and “State.”

Simulation Parameters 430 may relate to: an epicenter, impacted area (for simulation), impeded states (road inaccessible), non-impeded areas (road accessible); airports (in versus out of use), road, bridges, tunnels (OOS, duration), railways, ports, etc. (OOS, duration), etc. A level of magnitude and a duration of days (or other time metrics) and simulation period may be identified. Impacted areas may be identified as impacted in state, impacted out of state (not available for supply) and available for supply in a geographic area, as shown by 440.

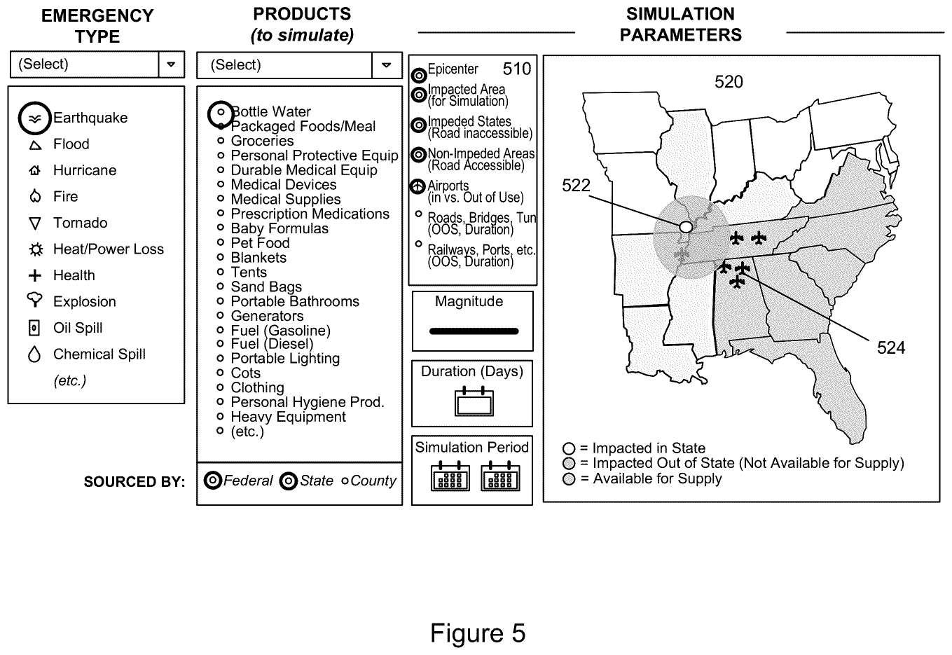

FIG. 5 is an exemplary user interface that illustrates an example of simulation parameters, according to an embodiment of the present invention. In this example, simulation parameters have been selected to include: an epicenter, impacted area (for simulation), impeded states (road inaccessible), non-impeded areas (road accessible); airports (in versus out of use), as shown by 510. Graphic 520 illustrates an epicenter at 522, airports by icon 524, impacted states and available for supply states. Graphic 520 further illustrates impacted in states, impacted out of state (not available for supply) and available for supply.

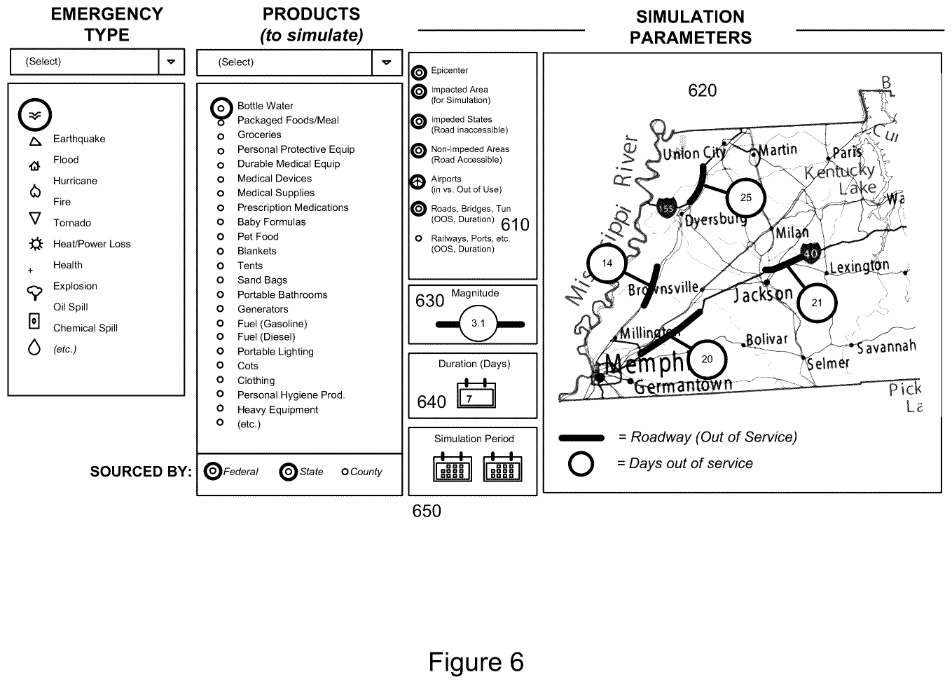

FIG. 6 is an exemplary user interface that illustrates an example of simulation parameters, according to an embodiment of the present invention. In this example, an additional simulation parameter directed to Roads, Bridges and Tunnels has been selected at 610. Graphic 620 illustrates roadways that are out of service and a corresponding number of days. Additional details may include Magnitude 630, Duration 640 and Simulation Period 650.

An embodiment of the present invention recognizes that response simulations may use analysis of past/historical data to obtain representative initial parameters for processes being simulated and predicted as well as initial assumptions. However, the transportation routes and times for movement of supplies, such as food and water, may vary depending on the circumstances and impact of an specific event, especially in relation to past experienced parameters/data. For example, wind and rain may vary based on geographic location and superposition of wind/rain magnitude of specific trucking routes based on storm distribution/track, or movement of a forest fire, or radioactive fallout dispersal. While a baseline parameter for average transit times based on actual speeds, or as a function of weather conditions based on past events or assumptions may be used initially, by continuous data collection, through mechanisms such as Internet of Things (IoT) and mobile data networks, actual GPS routes, speeds and transit times during an evolving event, models parameters may be dynamically updated and improved during the course of an event to more accurate and representative values. This may continuously improve the fidelity of the simulation during the course of an event, and during and in-between predictive simulation model calculation.

Accordingly, simulation parameters may be continuously updated based on data from tracked assets including GPS location, bar code and/or event data. For example, event data may be transmitted via RFID transmission and may include information relating to arrival, loading, unloading, dispatch, destination, distribution, etc.

In addition, an embodiment of the present invention may apply generative AI to extract the updated parameters from the continuous data stream (e.g., IoT, etc.).

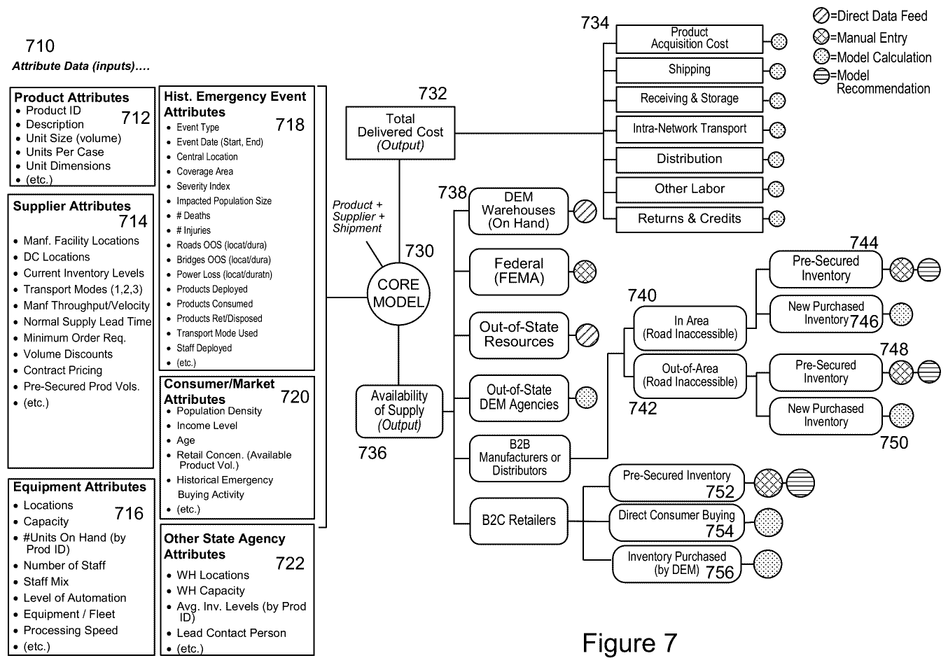

At step 216, core model components relating to a supply chain simulation may be activated. FIG. 7 is an exemplary user interface that illustrates attribute data inputs, according to an embodiment of the present invention.

For example, each box (on the right) may represent a unique set of attributes. Inputs may include Attribute Data 710. Attribute Data 710 may include Product Attributes 712, Supplier Attributes 714, Equipment Attributes 716 (e.g., TEMA attributes), Historical Emergency Event Attributes 718, Customer/Market Attributes 720, and Other State Agency Attributes 722.

Core Model 730 may receive input data relating to product, supplier and shipment. Core Model 730 may output Total Delivered Cost 732 which may be further represented by model calculation factors 734 including product acquisition cost, shipping, receiving and storage, intra-network transport, distribution, other labor and returns/credits. Core Model 730 may output Availability of Supply 736 which may be further represented by Factors 738 including DEM Warehouses (on hand), Federal (FEMA), other in-state resources, out-of-state DEM agencies, manufacturers/distributors and retailers. Some of the data relating to supply availability may be received through a data feed, such as DEM warehouses, in-state resources, etc. Others may be determined through model calculation, such as out-of-state agencies, new purchased inventory, direct consumer buying, etc.

Manufacturers/Distributors may further include In Area (road accessible) 740 and out of area (road inaccessible) 742. Inventory may include pre-secured 744, 748 and new purchased 746, 750. Retailers may further include pre-secured inventory 752, direct consumer buying 754 and inventory purchased 756. The model may provide recommendations relating to pre-secured inventory, for example.

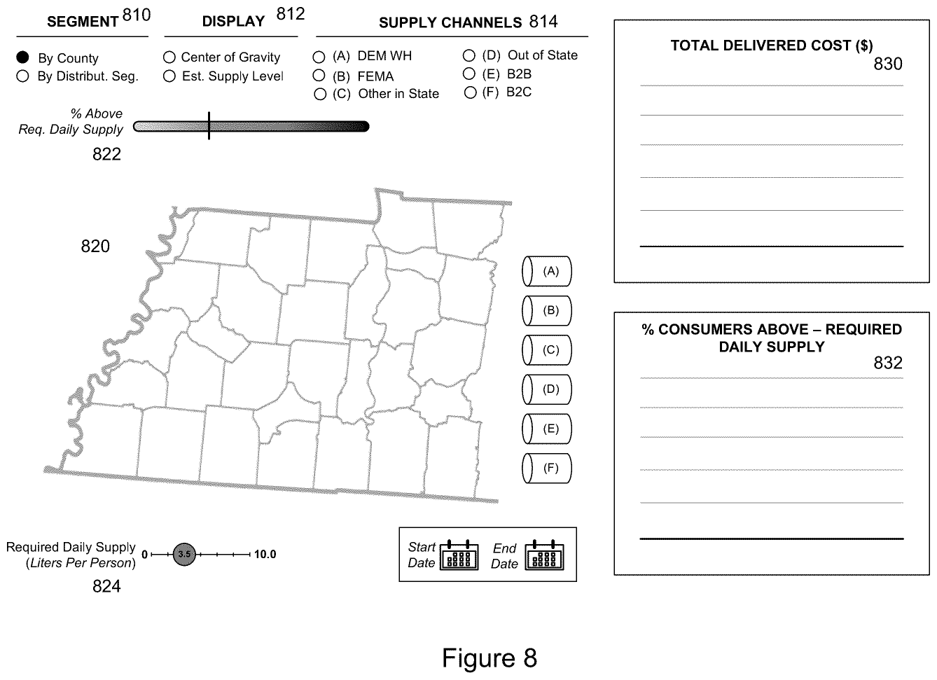

At step 218, a simulation to generate at least one supply chain result may be prepared. For example, the supply chain result comprises a total delivered cost and a number of consumers above a required daily supply. FIGS. 8-10 are exemplary user interfaces, according to an embodiment of the present invention.

FIG. 8 illustrates segment 810 (e.g., by county, by distribution segment), display 812 (e.g., center of gravity, estimated supply level) and supply channels 814. In the example of FIG. 8, Segment by county has been selected at 810.

Graphic 820 provides an interactive geographic region. Additional details may include: percentage above required daily supply 822 and required daily supply 824. FIG. 8 may also provide total delivered cost 830 and percentage of consumers above required daily supply 832. Other metrics may be provided.

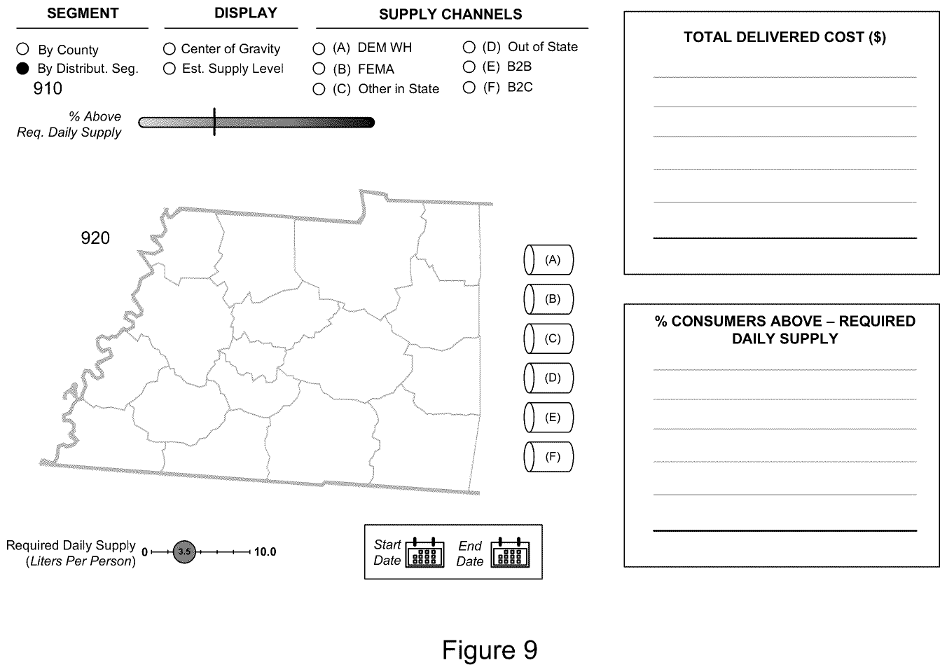

FIG. 9 provides an illustration by distribution segments where segments and importance may be based on population density, income, access to transportation, etc. In the example of FIG. 9, Segment by distribution segment has been selected at 910. Graphic 920 illustrates corresponding distribution segments.

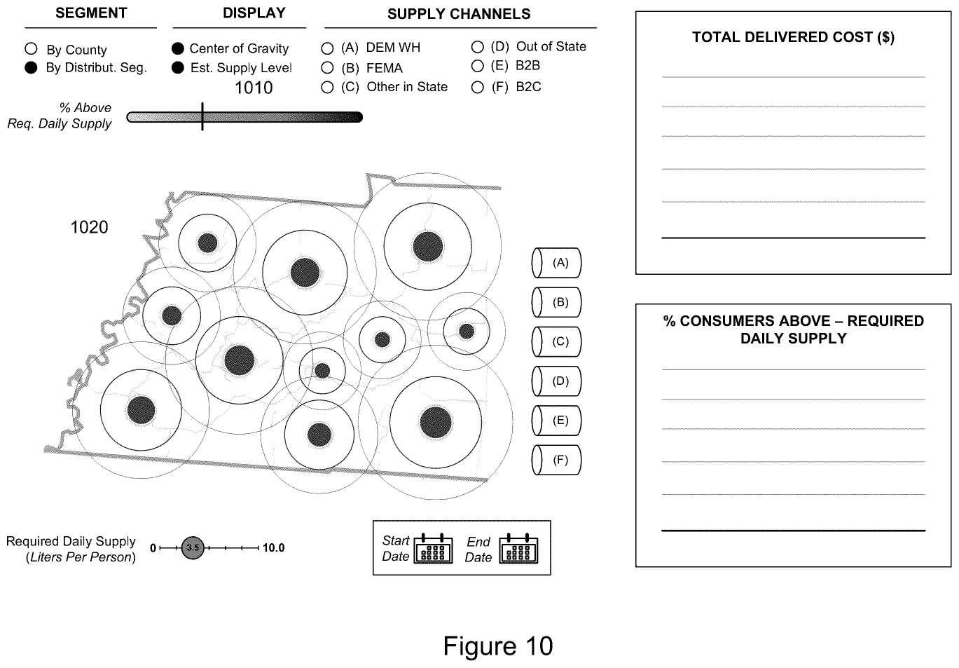

FIG. 10 is an exemplary user interface that illustrates center of gravity and estimated supply level, according to an embodiment of the present invention. In the example of FIG. 10, Center of Gravity and Estimated Supply Level have been selected at 1010. Graphic 1020 illustrates corresponding display metrics.

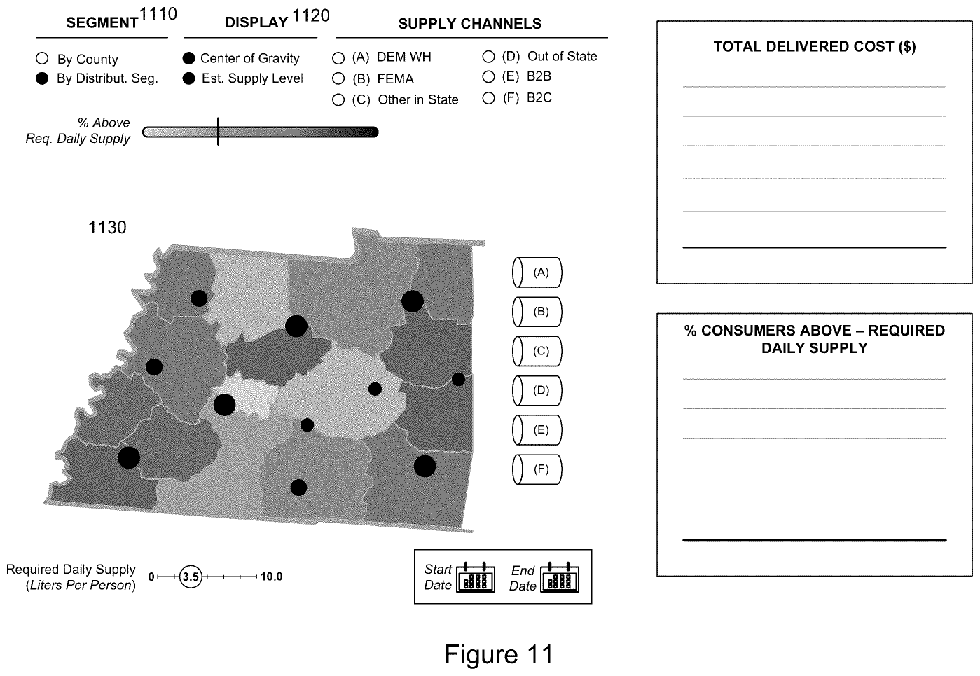

At step 220, the simulation may be executed. FIGS. 11-18 are exemplary user interfaces illustrated executed simulations, according to an embodiment of the present invention.

In the example of FIG. 11, distribution segments 1110 and center of gravity and estimated supply levels 1120 have been selected Graphic 1130 illustrates corresponding segment and display metrics.

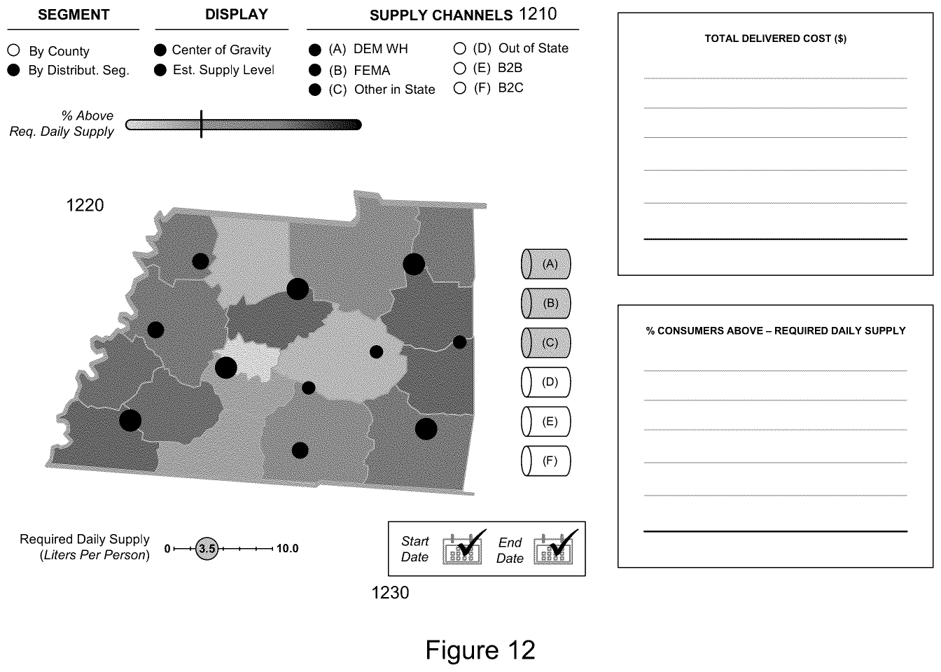

FIG. 12 is an exemplary user interface that illustrates supply channels, according to an embodiment of the present invention. In the example of FIG. 12, supply channels have been selected at 1210 and displayed in Graphic 1220. Start and end dates are selected at 1230. Graphic 1220 illustrates each supply channel, as shown by (A), (B) and (C).

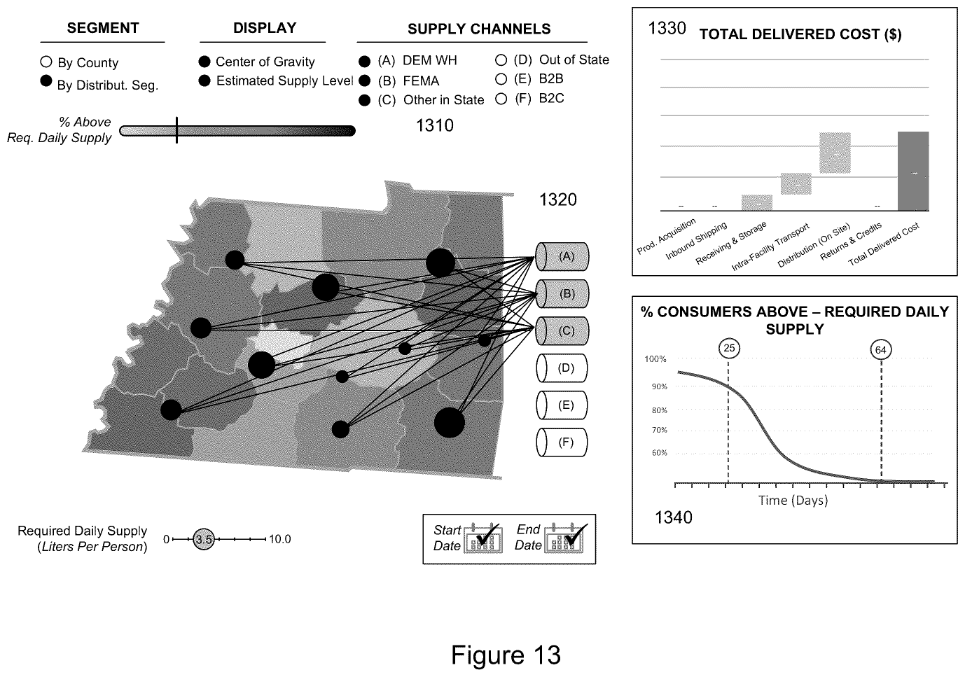

FIG. 13 provides total delivered cost and percentage of consumers above required daily supply graphics. In the example of FIG. 13, supply channels selected at 1310 are illustrated in Graphic 1320. Graphic 1320 illustrates each supply channel, as shown by (A), (B) and (C) and corresponding geographic regions. Additional graphics are shown as Total Delivered Costs at 1330 and Percentage of Consumers above a required daily supply at 1340.

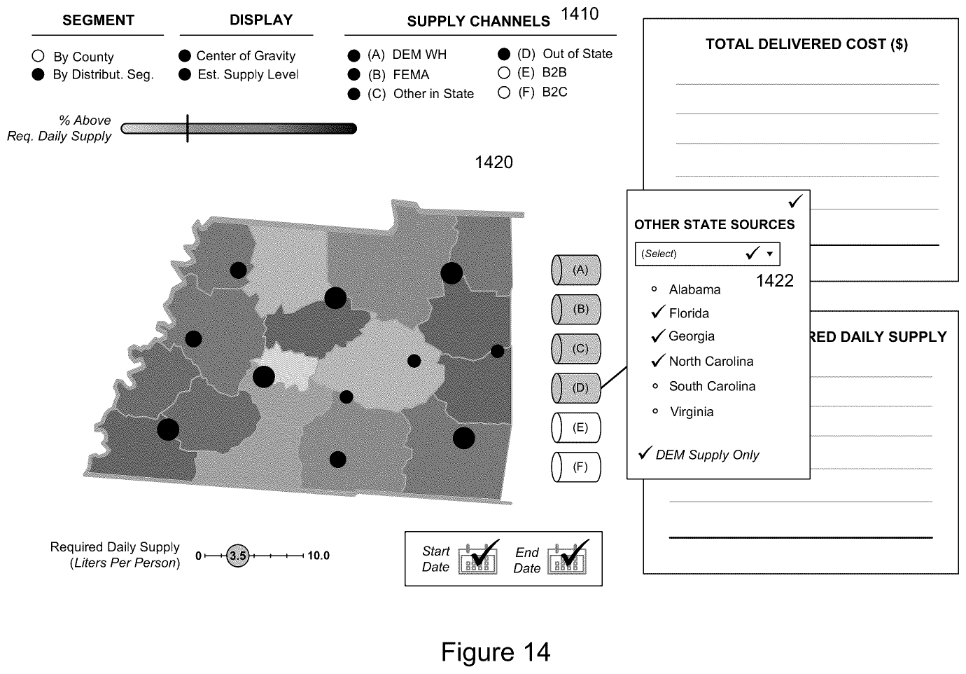

FIG. 14 is an exemplary user interface that illustrates other sources, according to an embodiment of the present invention. In the example of FIG. 14, an additional supply channel is selected at 1410 and illustrated in Graphic 1420. Other state sources may be detailed at 1422.

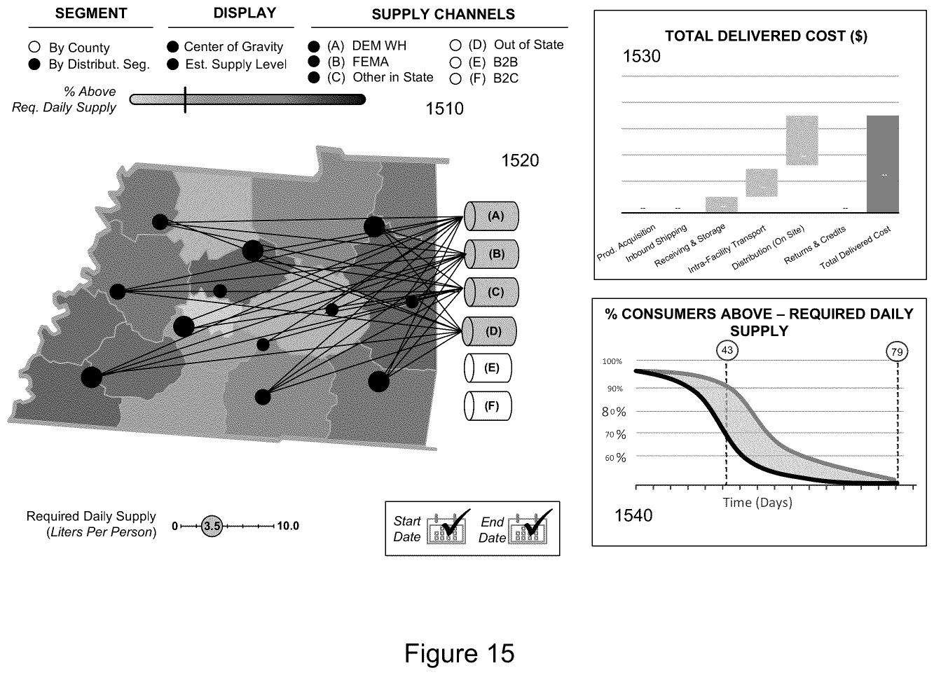

FIG. 15 is an exemplary user interface that illustrates an updated simulation, according to an embodiment of the present invention. In the example of FIG. 15, supply channels selected at 1510 are illustrated in Graphic 1520. Additional graphics are shown as Total Delivered Costs at 1530 and Percentage of Consumers above a required daily supply at 1540. Graphic 1540 may further include historical data to illustrate a comparison.

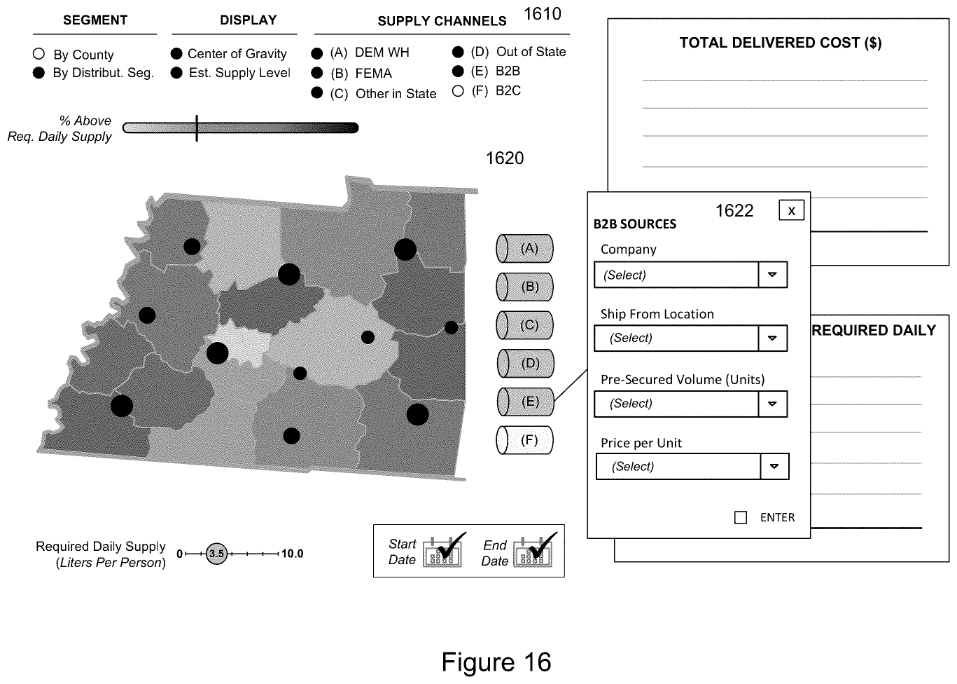

FIG. 16 is an exemplary user interface that illustrates an ability to provide source details, according to an embodiment of the present invention. In the example of FIG. 16, additional supply channels are selected at 1610 and illustrated in Graphic 1620. B2B sources may be detailed at 1622.

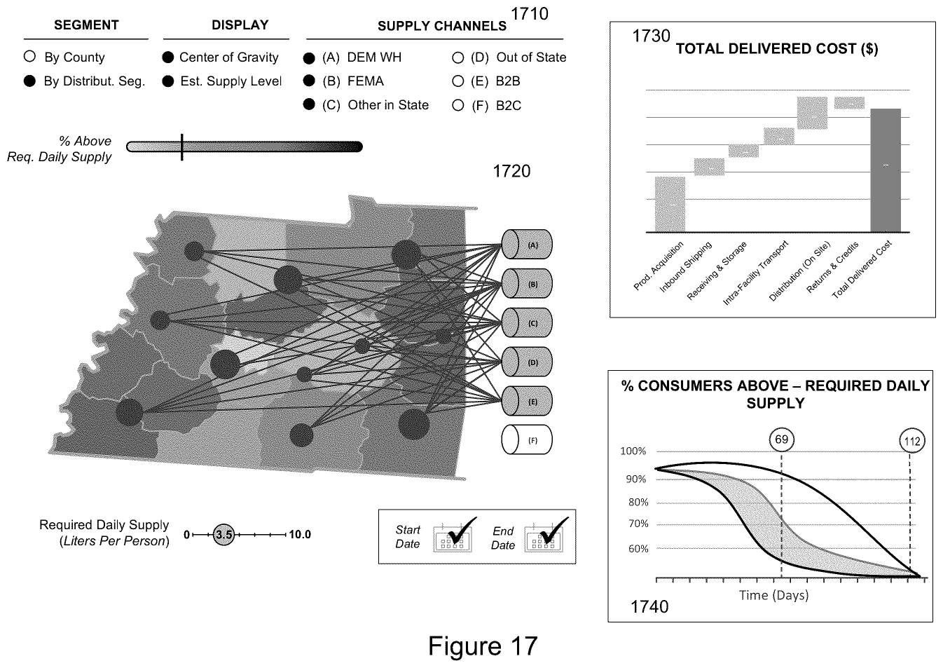

FIG. 17 is an exemplary user interface that illustrates an updated simulation, according to an embodiment of the present invention. In the example of FIG. 17, supply channels selected at 1710 are illustrated in Graphic 1720. Additional graphics are shown as Total Delivered Costs at 1730 and Percentage of Consumers above a required daily supply at 1740. Graphic 1740 may further include historical data to illustrate comparisons.

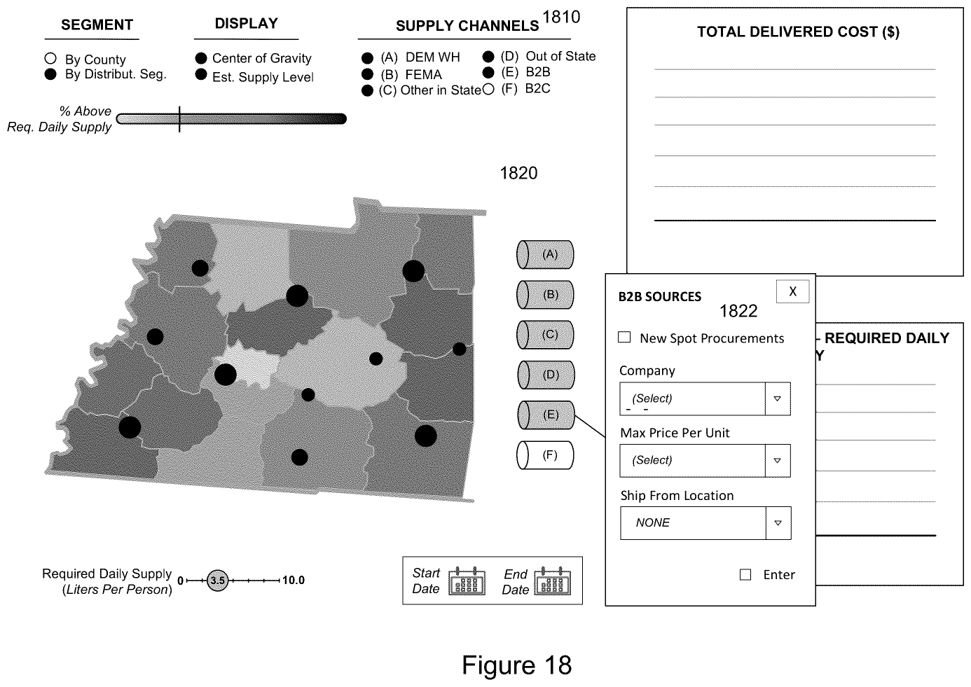

FIG. 18 is an exemplary user interface that illustrates updated source details, according to an embodiment of the present invention. In the example of FIG. 18, additional supply channels are selected at 1810 and illustrated in Graphic 1820. Other B2B sources may be detailed at 1822.

At step 212, results of the simulation may be examined through a graphical representation of the supply chain result.

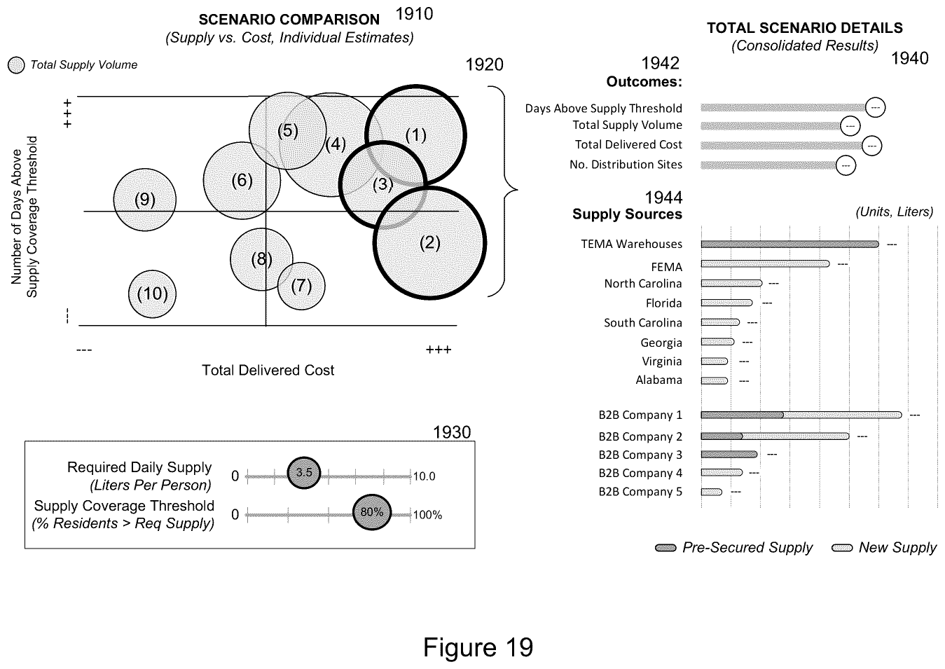

FIG. 19 is an exemplary user interface that illustrates scenario comparison details, according to an embodiment of the present invention. In this example, a scenario comparison, as shown by 1910, of individual estimates of supply versus costs may be provided. Section 1920 illustrates total supply volumes. A number of days above a supply cover threshold across a total delivered cost may be provided. Section 1930 illustrates required daily supply (liters per person) shown at 3.5 and a supply coverage threshold (percentage residents>required supply) at 80%. Section 1940 illustrates Outcomes 1942 and Supply Sources 1944.

Outcomes 1942 may include Days above supply threshold; total supply volume; total delivered cost and number of distribution sites. Supply Sources 1944 may include warehouses, FEMA, individual states and companies. Supplies may be identified as pre-secured or new.

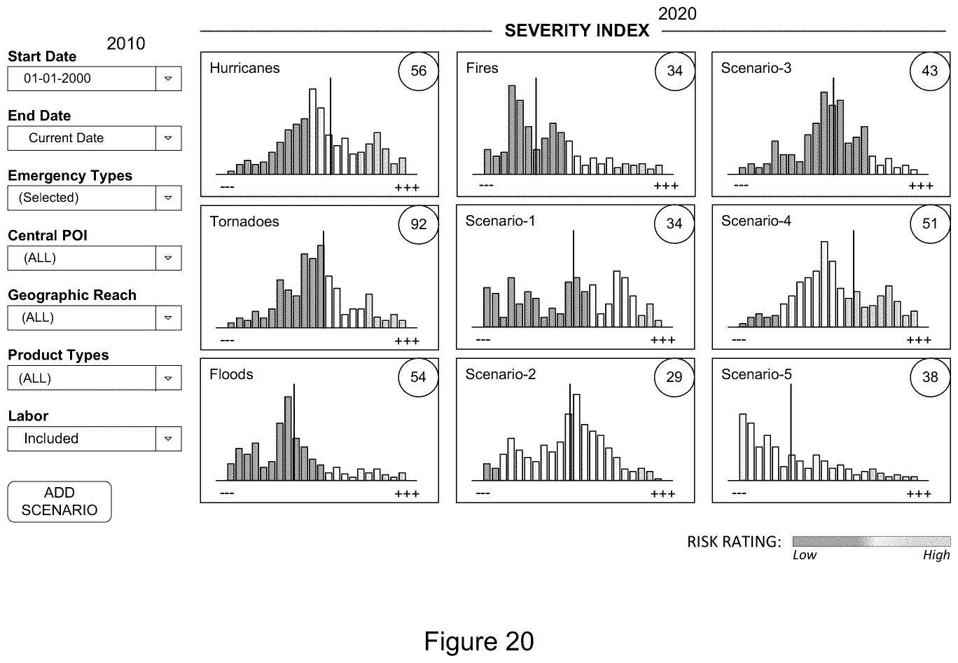

FIGS. 20-22 are exemplary user interfaces, according to an embodiment of the present invention.

FIG. 20 is an exemplary user interface that details severity index, according to an embodiment of the present invention. At Section 2010, various metrics may be identified including Start Date, End Date, Emergency Type, Central Point of Impact (POI), Geographic Reach, Product Types, and Labor. Based on these metrics, an embodiment of the present invention may identify emergency scenarios with corresponding severity indices as shown by 2020. Each scenario may be given a severity index with a graphical representation of the risk. Scenarios may include hurricanes, fires, tornadoes, floods, as well as other defined situations. Low Risk indicates that all supply needs can be fulfilled with current resources on hand; Medium Risk indicates that all supply needs can be fulfilled with reliance on resources outside DEM control and High Risk indicates reliance on non-DEM resources with a risk of supply shortage. Other metrics and measures of risk may be applied.

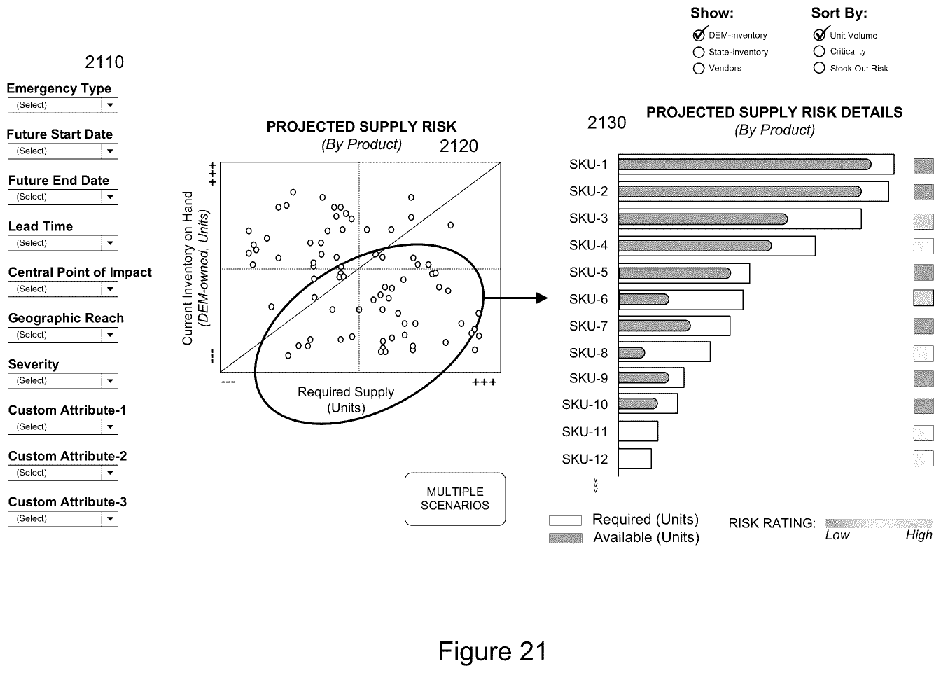

FIG. 21 is an exemplary user interface that provides projected supply risk, according to an embodiment of the present invention.

At Section 2110, various metrics may be identified including Emergency Type, Future Start Date, Future End Date, Lead Time, Central Point of Impact, Geographic Reach; Severity; and other various custom attributes. Based on these metrics, an embodiment of the present invention may identify a Projected Supply Risk by product at 2120. For example, current inventory on hand may be compared to a required supply. In response, projected supply risk details by product may be illustrated at 2130. Section 2130 graphically identifies required units and available units with a corresponding risk rating for each product (identified by SKU number or other reference/identifier). Low Risk indicates that all supply needs can be fulfilled with current resources on hand; Medium Risk indicates that all supply needs can be fulfilled with reliance on resources outside DEM control and High Risk indicates reliance on non-DEM resources with a risk of supply shortage.

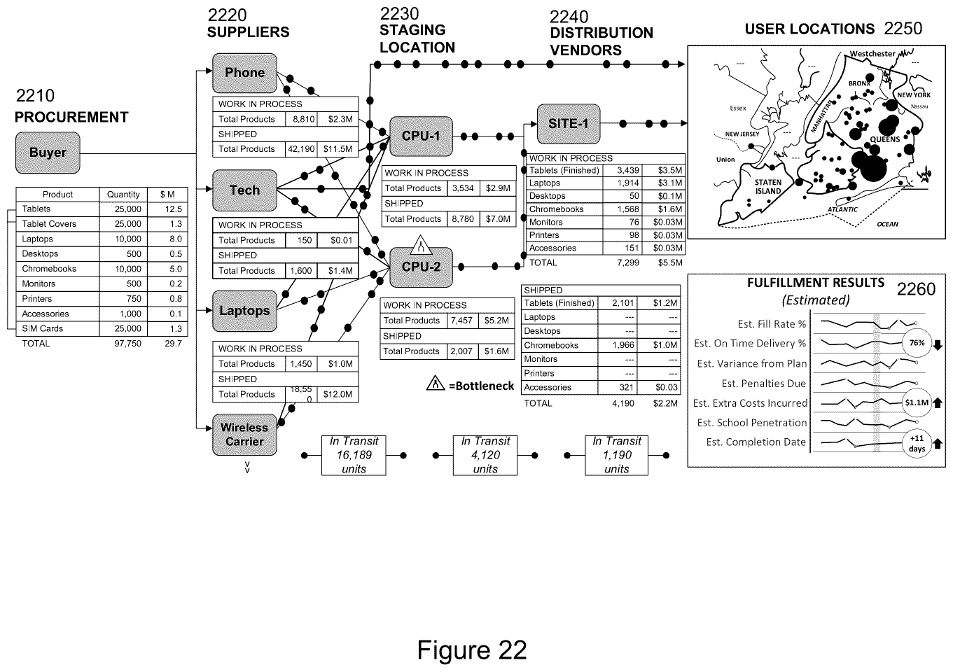

FIG. 22 is an exemplary user interface that provides procurement details including buyer 2210, suppliers 2220, staging locations 2230, distribution vendors 2240, user locations 2250 and fulfillment results 2260.

Buyer 2210 may secure various supplies as shown by products, quantity and dollar amount. Units in transit may be displayed by interconnections. Buyer 2210 may work with various Suppliers 2220 to secure supplies. Suppliers 2220 may provide various types of supplies. Status information may be displayed, including work in progress and shipped. Staging Locations 2230 may also represent work in progress and shipped products. Bottlenecks and other status indicators may be identified. Distribution Vendors 2240 may include work in process and shipped status information for various products, including tablets, laptops, desktops, monitors, printers, accessories, etc. User Locations 2250 may graphically display user concentration. Fulfillment Results 2260 may be provided including various estimates, such as fill rate, on time delivery, variance from plan, penalties due, extra costs incurred, school penetration, completion date. Trending data may also be provided.

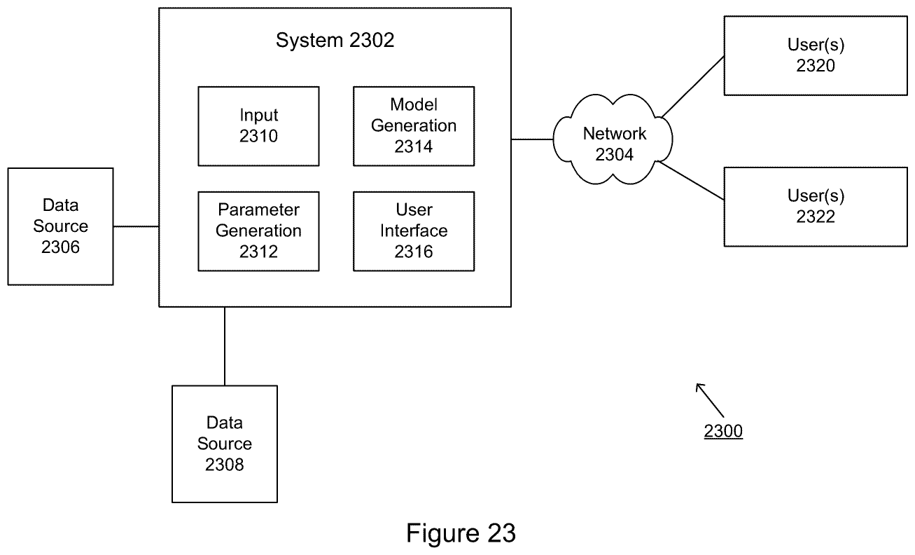

FIG. 23 is an exemplary system diagram, according to an embodiment of the present invention. An embodiment of the present invention is directed to simulating potential outcomes in various enterprise level events incorporating the procurement and use of materials from multiple sources. According to an embodiment of the present invention, Emergency Management develops effective plans, training and data analytics that lead to more resilient communities and states. The supply chain innovations of an embodiment of the present invention may leverage big data, advanced analytics, and/or AI/ML to significantly improve supply chain resiliency, emergency preparedness and response operations.

As shown in FIG. 23, Users 2320, 2322 may access System 2302 via Network 2304. System 2302 may receive data from various sources represented by Data Sources 2306, 2308 which may include internal as well as external sources of information. System 2302 may be a stand-alone system or integrated with various other systems and platforms. Other implementations and architectures may be supported.

System 2302 may support various features and functions represented by Input 2210, Parameter Generation 2312, Model Generation 2314, User Interface 2316, etc.

Input 2310 may receive/ingest data from various data sources, including Data Sources 2306, 2308. Data Sources 2306, 2308 may store and manage supplier data, product data, external data, government data, etc.

Parameter Generation 2312 may generate one or more simulation parameters relating to an emergency type and products/services to simulate.

Model Generation 2314 may generate a model to replicate an emergency scenario using the generated simulation parameters.

User Interface 2316 may provide an interactive interface that provides analysis in various formats, including dashboards, interactive interfaces, and/or other communications. User Interface 2316 may be accessed by various user devices over communication network represented by Network 2304.

Users may communicate with System 2302 via Network 2304. System 2302 may communicate and integrate with other devices and support various configurations and architectures. System 2302 may support interactions on devices including mobile or computing device, such as a laptop computer, a personal digital assistant, a smartphone, a smartwatch, smart glasses, other wearables or other computing devices capable of sending or receiving network signals. System 2302 may include computer components such as computer processors, microprocessors and interfaces to support applications including browsers, mobile interfaces, dashboards, interactive interfaces, etc. Other functions and features represented may be supported in various forms and implementations. While FIG. 23 illustrates individual devices or components, it should be appreciated that there may be several of such devices to carry out the various exemplary embodiments.

System 2302 may be communicatively coupled to various data sources including any suitable data structure to maintain the information and allow access and retrieval of the information. Data Sources 2306, 2308 may be local, remote, cloud or network based. Communications with Data Sources 2306, 2308 may be over a network, or communications may involve a direct connection.

Networks may be a wireless network, a wired network or any combination of wireless network and wired network. Although Network 2304 is depicted as one network for simplicity, it should be appreciated that according to one or more embodiments, Network 2304 may comprise a plurality of interconnected networks, such as, for example, a service provider network, the Internet, a cellular network, corporate networks, or even home networks, or any of the types of networks mentioned above. Data may be transmitted and received via Network 2304 utilizing a standard networking protocol or a standard telecommunications protocol.

The system 2300 of FIG. 23 may be implemented in a variety of ways. Architecture within system 2300 may be implemented as hardware components (e.g., module) within one or more network elements. It should also be appreciated that architecture within system 2300 may be implemented in computer executable software (e.g., on a tangible, non-transitory computer-readable medium) located within one or more network elements. Module functionality of architecture within system 2300 may be located on a single device or distributed across a plurality of devices including one or more centralized servers and one or more mobile units or end user devices. The architecture depicted in system 2300 is meant to be exemplary and non-limiting. For example, while connections and relationships between the elements of system 2300 are depicted, it should be appreciated that other connections and relationships are possible. The system 2300 described below may be used to implement the various methods herein, by way of example. Various elements of the system 2300 may be referenced in explaining the exemplary methods described herein.

It will be appreciated by those persons skilled in the art that the various embodiments described herein are capable of broad utility and application. Accordingly, while the various embodiments are described herein in detail in relation to the exemplary embodiments, it is to be understood that this disclosure is illustrative and exemplary of the various embodiments and is made to provide an enabling disclosure. Accordingly, the disclosure is not intended to be construed to limit the embodiments or otherwise to exclude any other such embodiments, adaptations, variations, modifications and equivalent arrangements.

The foregoing descriptions provide examples of different configurations and features of embodiments of the invention. While certain nomenclature and types of applications/hardware are described, other names and application/hardware usage is possible and the nomenclature is provided by way of non-limiting examples only. Further, while particular embodiments are described, it should be appreciated that the features and functions of each embodiment may be combined in any combination as is within the capability of one skilled in the art. The figures provide additional exemplary details regarding the various embodiments.

Various exemplary methods are provided by way of example herein. The methods described can be executed or otherwise performed by one or a combination of various systems and modules.

The use of the term computer system in the present disclosure can relate to a single computer or multiple computers. In various embodiments, the multiple computers can be networked. The networking can be any type of network, including, but not limited to, wired and wireless networks, a local-area network, a wide-area network, and the Internet.

According to exemplary embodiments, the System software may be implemented as one or more computer program products, for example, one or more modules of computer program instructions encoded on a computer-readable medium for execution by, or to control the operation of, data processing apparatus. The implementations can include single or distributed processing of algorithms. The computer-readable medium can be a machine-readable storage device, a machine-readable storage substrate, a memory device, or a combination of one or more them. The term “processor” encompasses all apparatus, devices, and machines for processing data, including by way of example a programmable processor, a computer, or multiple processors or computers. The apparatus can include, in addition to hardware, software code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed for execution on one computer or on multiple computers that are located at one site or distributed across multiple sites and interconnected by a communications network.

A computer may encompass all apparatus, devices, and machines for processing data, including by way of example a programmable processor, a computer, or multiple processors or computers. It can include, in addition to hardware, code that creates an execution environment for the computer program in question, e.g., code that constitutes processor firmware, a protocol stack, a database management system, an operating system, or a combination of one or more of them.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Computer-readable media suitable for storing computer program instructions and data can include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While the embodiments have been particularly shown and described within the framework for conducting analysis, it will be appreciated that variations and modifications may be affected by a person skilled in the art without departing from the scope of the various embodiments. Furthermore, one skilled in the art will recognize that such processes and systems do not need to be restricted to the specific embodiments described herein. Other embodiments, combinations of the present embodiments, and uses and advantages of the will be apparent to those skilled in the art from consideration of the specification and practice of the embodiments disclosed herein. The specification and examples should be considered exemplary.

What is claimed is:

1. A computer-implemented system for implementing a simulation tool that analyzes and projects procurement data for various emergency events, the system comprising:
an input that communicates with one or more data sources;
a memory component that stores and manages data from the one or more data sources; and
a computer processor coupled to the interface and the memory component and further programmed to perform the steps of:
identifying one or more inquiries relating to a supply chain projection in an emergency event;
importing, via the input, one or more data files relating to an enterprise supply chain relevant to the emergency event wherein the one or more data files comprise:
supplier data, product data, external data and government data;
identifying, via the computer processor, a set of simulation parameters wherein the set of simulation parameters relate to an emergency type and one or more products to simulate;
responsive to the set of simulation parameters, activating a set of core model components relating to a supply chain simulation;
executing the supply chain simulation to generate at least one supply chain result, wherein the supply chain result comprises a total delivered cost and a number of consumers above a required daily supply; and
providing, via an interface, a graphical representation of the at least one supply chain result.

2. The system of claim 1, wherein at least one of the set of simulation parameters is continuously updated based on data from one or more tracked assets comprising at least one of: GPS location, barcode, and event data.

3. The system of claim 2, wherein the event data is transmitted via RFID transmission and comprises at least one of: arrival, load, unload, dispatch, destination, and distribution information.

4. The system of claim 1, wherein the emergency type comprises: Earthquake, Flood, Hurricane, Fire, Tornado, Heat/Power Loss, Health, Explosion, Oil Spill, and Chemical Spill.

5. The system of claim 1, wherein the one or more products to simulate comprises: food, water, protective equipment, medical equipment, medical supplies, mediations, personal hygiene products, equipment and fuel.

6. The system of claim 1, wherein the set of simulation parameters relate to one or more of: epicenter, impacted area, impeded areas, non-impeded areas, airports, roads, bridges, tunnels and ports.

7. The system of claim 1, wherein the set of core model components receive inputs comprising product attributes, supplier attributes, historical emergency event attributes and consumer/market attributes and wherein the set of core model components generate outputs comprising: total delivered costs and availability of supply.

8. The system of claim 1, wherein the graphical representation comprises: segment by county or distribution segment; display of center of gravity and estimated supply level; and one or more supply chains.

9. The system of claim 1, wherein the graphical representation comprises: a scenario comparison of supply coverage threshold and total delivered costs.

10. The system of claim 1, wherein the graphical representation comprises: a projected supply risk based on current inventory on hand and required supply.

11. A computer-implemented method for implementing a simulation tool that analyzes and projects procurement data for various emergency events, the method comprising the steps of:
identifying, via an input, one or more inquiries relating to a supply chain projection in an emergency event;
importing, via the input, one or more data files relating to an enterprise supply chain relevant to the emergency event wherein the one or more data files comprise: supplier data, product data, external data and government data;
identifying, via a computer processor, a set of simulation parameters wherein the set of simulation parameters relate to an emergency type and one or more products to simulate;
responsive to the set of simulation parameters, activating a set of core model components relating to a supply chain simulation;
executing the supply chain simulation to generate at least one supply chain result, wherein the supply chain result comprises a total delivered cost and a number of consumers above a required daily supply; and
providing, via a user interface, a graphical representation of the at least one supply chain result.

12. The method of claim 11, wherein at least one of the set of simulation parameters is continuously updated based on data from one or more tracked assets comprising at least one of: GPS location, barcode, and event data.

13. The method of claim 12, wherein the event data is transmitted via RFID transmission and comprises at least one of: arrival, load, unload, dispatch, destination, and distribution information.

14. The method of claim 11, wherein the emergency type comprises: Earthquake, Flood, Hurricane, Fire, Tornado, Heat/Power Loss, Health, Explosion, Oil Spill, and Chemical Spill.

15. The method of claim 11, wherein the one or more products to simulate comprises: food, water, protective equipment, medical equipment, medical supplies, mediations, personal hygiene products, equipment and fuel.

16. The method of claim 11, wherein the set of simulation parameters relate to one or more of: epicenter, impacted area, impeded areas, non-impeded areas, airports, roads, bridges, tunnels and ports.

17. The method of claim 11, wherein the set of core model components receive inputs comprising product attributes, supplier attributes, historical emergency event attributes and consumer/market attributes and wherein the set of core model components generate outputs comprising: total delivered costs and availability of supply.

18. The method of claim 11, wherein the graphical representation comprises: segment by county or distribution segment; display of center of gravity and estimated supply level; and one or more supply chains.

19. The method of claim 11, wherein the graphical representation comprises: a scenario comparison of supply coverage threshold and total delivered costs.

20. The method of claim 11, wherein the graphical representation comprises: a projected supply risk based on current inventory on hand and required supply.
